(19) United States
(12) Patent Application Publication
(10) Pub. No.: US 2025/0140628 A1
(43) Pub. Date: May 1, 2025

(54) DIELECTRIC LAYER PROTRUSIONS

(71) Applicant: TEXAS INSTRUMENTS INCORPORATED, Dallas, TX (US)

(72) Inventor: Enis TUNCER, Dallas, TX (US)

(21) Appl. No.: 18/497,424

(22) Filed: Oct. 30, 2023

(51) Int. Cl. H01L 23/31; H01L 21/56; H01L 23/00

(52) U.S. Cl. CPC H01L 23/3192; H01L 21/56; H01L 23/3128; H01L 23/3135; H01L 24/13; H01L 24/16; H01L 2224/13147; H01L 2224/16225

(57) ABSTRACT

A package comprises a semiconductor die having a device side in which circuitry is formed and first and second metal members coupled to and extending away from the device side. The package also comprises a passivation layer contacting the device side, at least a portion of the passivation layer positioned between the first and second metal members, the passivation layer including a top surface facing away from the semiconductor die. The package further comprises multiple passivation layer protrusions (PLPs) coupled to and extending away from the top surface, the multiple PLPs having heights ranging from 0.5 microns to 50 microns.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. Dies are then coupled to a lead frame and are covered by a mold compound, which is subsequently sawn to produce a package.

### SUMMARY

A package comprises a semiconductor die having a device side in which circuitry is formed and first and second metal members coupled to and extending away from the device side. The package also comprises a passivation layer contacting the device side, at least a portion of the passivation layer positioned between the first and second metal members, the passivation layer including a top surface facing away from the semiconductor die. The package further comprises multiple passivation layer protrusions (PLPs) coupled to and extending away from the top surface, the multiple PLPs having heights ranging from 0.5 microns to 50 microns.

A method for manufacturing a package comprises applying a first passivation layer on a device side of a semiconductor die, the device side including circuitry and a pair of metal members extending away from the device side. The method also comprises applying a second passivation layer on the first passivation layer. The method further comprises patterning the second passivation layer using photolithography to produce multiple passivation layer protrusions positioned between the pair of metal members and extending away from the semiconductor die, the multiple passivation layer protrusions having heights ranging from 0.5 microns to 50 microns and a density ranging from 1 unit per square micron to 100 units per square micron.

### BRIEF DESCRIPTION OF THE DRAWINGS

FIG. 1 is a block diagram of an electronic device including a package having passivation and/or polyimide layer protrusions, in accordance with various examples.

FIG. 2A is a profile, cross-sectional view of a package having passivation layer protrusions, in accordance with various examples.

FIG. 2B is a top-down view of a package having passivation layer protrusions, in accordance with various examples.

FIG. 2C is a perspective view of a package having passivation layer protrusions, in accordance with various examples.

FIG. 3A is a profile, cross-sectional view of a package having passivation and polyimide layer protrusions, in accordance with various examples.

FIG. 3B is a top-down view of a package having passivation and polyimide layer protrusions, in accordance with various examples.

FIG. 3C is a perspective view of a package having passivation and polyimide layer protrusions, in accordance with various examples.

FIG. 4A is a profile view of rectangular passivation and/or polyimide layer protrusions, in accordance with various examples.

FIG. 4B is a top-down view of rectangular passivation and/or polyimide layer protrusions, in accordance with various examples.

FIG. 4C is a perspective view of rectangular passivation and/or polyimide layer protrusions, in accordance with various examples.

FIG. 5A is a profile view of star-shaped passivation and/or polyimide layer protrusions, in accordance with various examples.

FIG. 5B is a top-down view of star-shaped passivation and/or polyimide layer protrusions, in accordance with various examples.

FIG. 5C is a perspective view of star-shaped passivation and/or polyimide layer protrusions, in accordance with various examples.

FIG. 6A is a profile view of arc-shaped passivation and/or polyimide layer protrusions, in accordance with various examples.

FIG. 6B is a top-down view of arc-shaped passivation and/or polyimide layer protrusions, in accordance with various examples.

FIG. 6C is a perspective view of arc-shaped passivation and/or polyimide layer protrusions, in accordance with various examples.

FIGS. 7A-7D are electric field distributions achieved in baseline packages and packages including passivation and/or polyimide layer protrusions, in accordance with various examples.

FIG. 8 is a flow diagram of a method for manufacturing a package including passivation layer protrusions, in accordance with various examples.

FIGS. 9A-9D is a process flow for manufacturing a package including passivation layer protrusions, in accordance with various examples.

FIG. 10 is a flow diagram of a method for manufacturing a package including passivation and polyimide layer protrusions, in accordance with various examples.

FIGS. 11A-11G is a process flow for manufacturing a package including passivation and polyimide layer protrusions, in accordance with various examples.

### DETAILED DESCRIPTION

Packages include semiconductor dies that have device sides in which circuitry is formed. The device sides may include metal members, such as copper pillars, under bump metallizations (UBMs), metal traces, and so on. Dielectric layers such as passivation layers and polyimide layers may be stacked on the device side of a semiconductor die. The metal members may extend through such dielectric layers, or a network of metal members coupled to each other may extend through the dielectric materials.

Frequently, electric charge will migrate across the surface of a dielectric layer. More specifically, charge may creep along an interface of the passivation layer and the polyimide layer from a first metal member (e.g., a copper pillar) to a second metal member (e.g., another copper pillar). Similarly, charge may creep along an interface of the polyimide layer and a mold compound from the first metal member to the second metal member. This charge can cause substantial damage. Interface defects, metallic ion transport, and other such irregularities can likewise cause damage. Damage can include dielectric failures or breakdowns, metal corrosion, metal migration (e.g., causing short circuits), and leakage failures. Such damage can cause package defects and device malfunction.

This disclosure describes various examples of packages having passivation and polyimide layer protrusions that mitigate the challenges described above. The protrusions extend away from the surfaces of passivation and/or polyimide layers along which electric charges may creep. The protrusions have specific physical dimensions and shapes that inhibit charge creep between metal members along the passivation-polyimide interface and along the polyimide-mold compound interface. More generally, the protrusions inhibit charge creep between metal members along any dielectric-to-dielectric interface along which charges might otherwise creep. In examples, the protrusions trap or store charge that would otherwise creep from one metal member to another along a dielectric interface. In example packages, a semiconductor die has a device side in which circuitry is formed and first and second metal members coupled to and extending away from the device side. A passivation layer contacts the device side, and at least a portion of the passivation layer is positioned between the first and second metal members. The passivation layer includes a top surface facing away from the semiconductor die. Multiple passivation layer protrusions (PLPs) are coupled to and extend away from the top surface. The multiple PLPs have heights ranging from the submicron level (i.e., 0.5 microns) to several microns (i.e., 50 microns). By discouraging charge creep across dielectric interfaces, the aforementioned damage is mitigated.

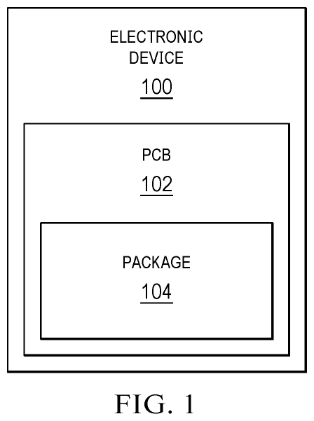

FIG. 1 is a block diagram of an electronic device 100 including a package having passivation and/or polyimide layer protrusions, in accordance with various examples. For example, the electronic device 100 may include a personal computer, a laptop, a desktop, a notebook, a tablet, a smartphone, an appliance (e.g., refrigerator, television, audio player, video player, video recorder, lighting device, etc.), an automobile, an aircraft, a spacecraft, etc. The electronic device 100 may include a printed circuit board (PCB) 102. In turn, a package 104 may be coupled to the PCB 102. The package 104 may be any type of package in which charge may creep along a dielectric interface between metal components of the package, such as a wafer chip scale package (WCSP), a dual inline package (DIP), a quad flat no lead (QFN) package, etc. Examples of the package 104 are now described with reference to the drawings.

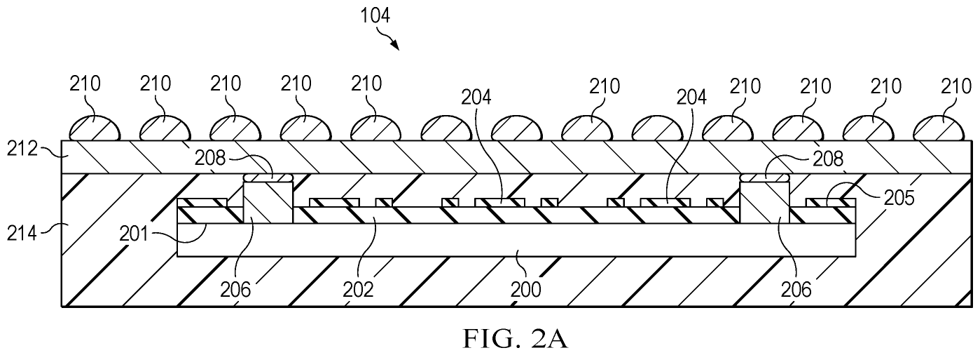

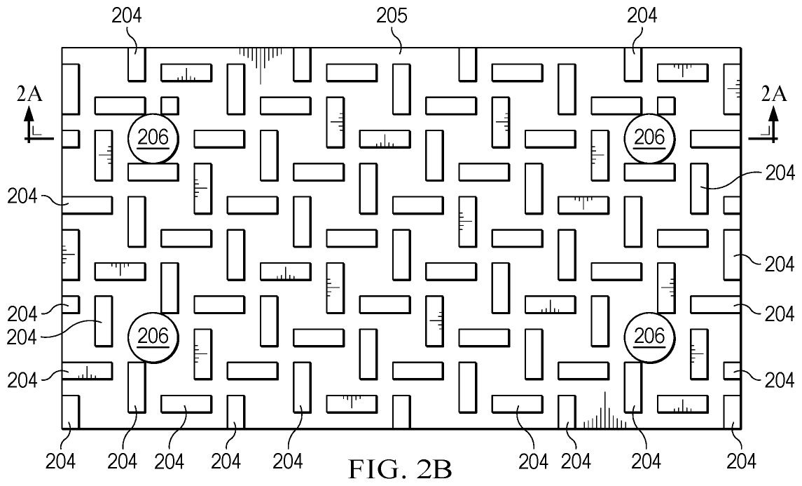

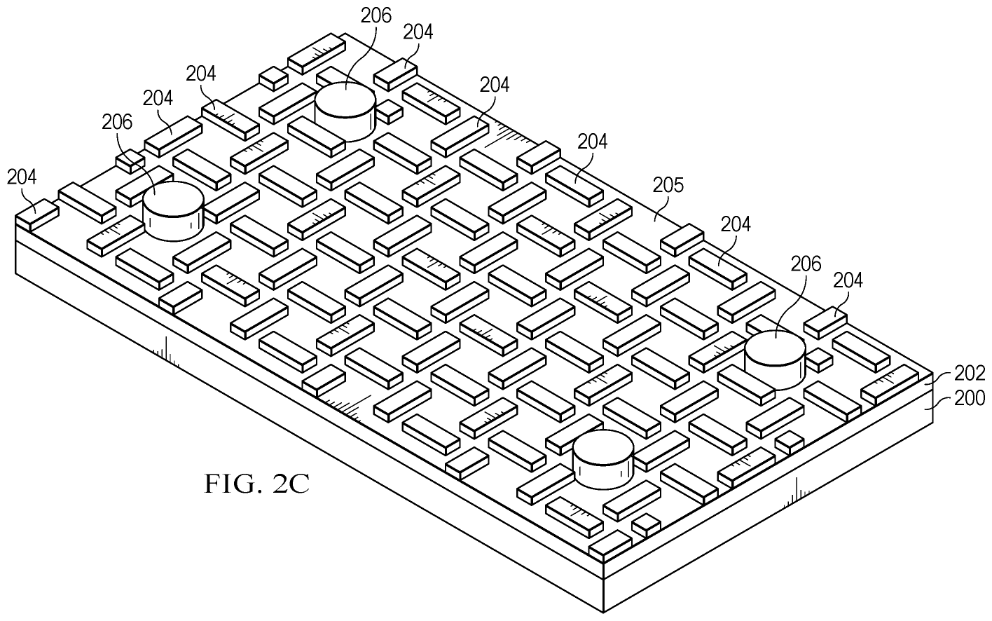

FIG. 2A is a profile, cross-sectional view of a package 104 having passivation layer protrusions, in accordance with various examples. The example package 104 includes a semiconductor die 200. The die 200 includes a device side 201 in which circuitry is formed. A dielectric layer 202, such as a passivation overcoat (PO) layer, contacts and covers the device side 201 of the die 200. As described in greater detail below, the dielectric layer 202 includes a surface 205 facing away from the die 200 and the device side 201, where the surface 205 is coupled to multiple protrusions 204. Metal members 206 are coupled to the device side 201. For example, the metal members 206 comprise copper. The protrusions 204 are located at least between the metal members 206, as shown, although the metal members 206 may also be included on other areas of the surface 205. Solder members 208 couple the metal members 206 to metal bumps 210 through a redistribution layer (RDL) 212. The RDL 212 includes a network of metal members that provide electrical pathways between the metal members 206 and the metal bumps 210. A mold compound 214 covers the various structures of the package 104 as shown. The mold compound 214 is a dielectric material and contacts the surface 205 and the protrusions 204. FIG. 2B is a top-down view of the package 104 of FIG. 2A having passivation layer protrusions, in accordance with various examples. FIG. 2C is a perspective view of the package 104 of FIG. 2A having passivation layer protrusions, in accordance with various examples.

As shown in FIGS. 2A-2C, the protrusions 204 extend from the surface 205 in the direction away from the die 200. The protrusions 204 may be of any suitable shape, with FIGS. 2A-6C depicting some illustrative, non-limiting shapes (e.g., having horizontal cross-sections that are rectangular, star-shaped, arc-shaped, etc.). The protrusions 204 form a lattice pattern on the surface 205, with the protrusions 204 in close proximity to each other but not touching each other, and with the protrusions 204 forming a regular pattern on the surface 205. The lattice pattern is such that the protrusions 204 form a barrier to a direct line-of-sight between any two metal members 206, meaning that a straight line cannot be drawn between any two metal members 206 along the surface 205 without intersecting at least one, if not multiple, of the protrusions 204. The pitch between the protrusions 204 ranges from 0.5 microns to 10 microns, with a pitch below this range being disadvantageous because the charge density would cover a region larger than the distance between protrusions 204 and would render the protrusions 204 minimally effective, and with a pitch above this range being disadvantageous because the charge would be mobile over the surface and would negatively influence device performance. The density of the protrusions 204 ranges from 1 units per square micron to 100 units per square micron, with a density below this range being disadvantageous because the charge density would cover a region larger than the distance between protrusions 204 and would render the protrusions 204 minimally effective, and with a density above this range being disadvantageous because the charge would be mobile over the surface and would negatively influence device performance.

The protrusions 204 have heights ranging from 0.5 microns to 50 microns, with a height below this range being disadvantageous because the charge will creep over short heights of protrusions 204 and electric field distributions will not be adequately controlled, and with a height above this range being disadvantageous because of manufacturing limitations. The protrusions 204 have widths ranging from 0.5 microns to 50 microns, with widths below this range being disadvantageous because electrical field distributions will not be adequately controlled, and with widths above this range being disadvantageous because the charge will move large distances to cause device malfunction. The protrusions 204 have lengths ranging from 0.5 microns to 50 microns, with lengths below this range being disadvantageous because electrical field distributions will not be adequately controlled, and with lengths above this range being disadvantageous because charge will move large distances to cause device malfunction.

The protrusions 204 may have the same orientation in space. For example, if the protrusions 204 are rectangular prisms, some or all of the protrusions 204 may be oriented parallel to each other on the surface 205. In examples, the protrusions 204 are oriented differently in space. For example, as shown in FIGS. 2B and 2C, some protrusions 204 are oriented orthogonally to other protrusions 204.

The protrusions 204 may comprise the same material (e.g., a passivation material) as that with which the dielectric layer 202 is formed. The protrusions 204 may comprise different material from that with which the dielectric layer 202 is formed. Example materials that may be used to form the dielectric layer 202, the protrusions 204, or both include silicon nitride, silicon dioxide, and silicon oxynitride. Neither the dielectric layer 202 nor the protrusions 204 cover the metal members 206.

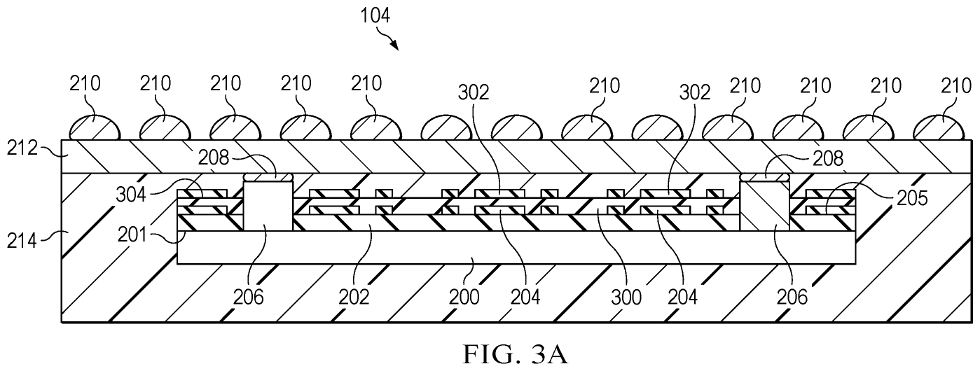

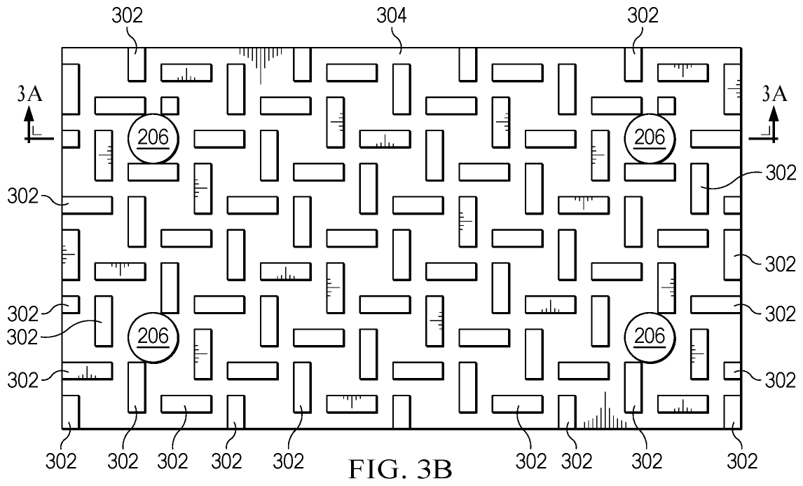

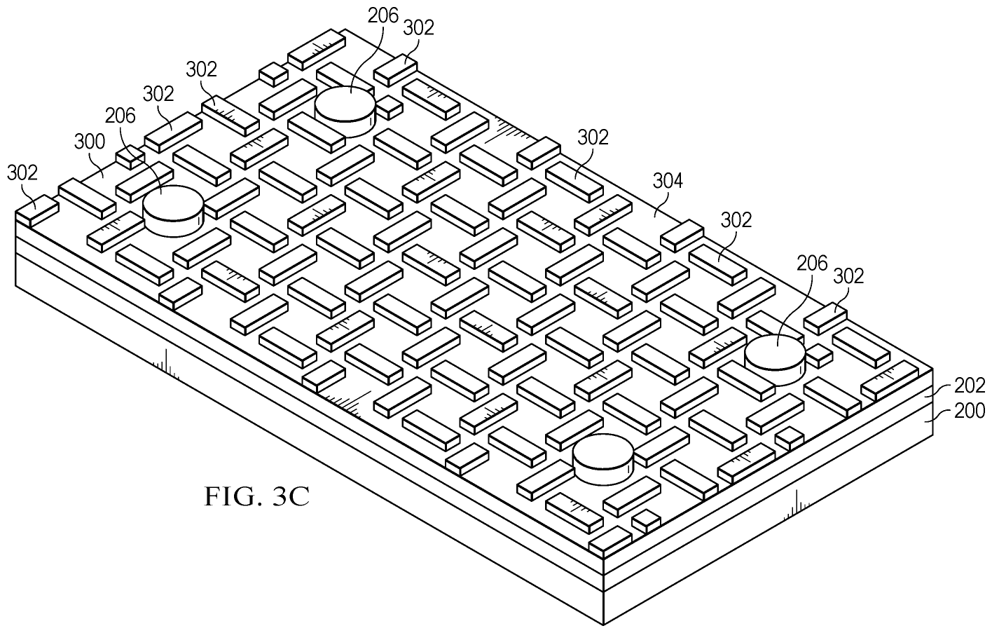

FIG. 3A is a profile, cross-sectional view of a package 104 having passivation and polyimide layer protrusions, in accordance with various examples. The package 104 of FIG. 3A is identical to the package 104 of FIG. 2A, except that the package 104 of FIG. 3A includes an additional dielectric layer 300 contacting the protrusions 204 and the surface 205 of the dielectric layer 202. In examples, the dielectric layer 300 is a polyimide layer. The dielectric layer 300 is coupled to and contacts multiple protrusions 302 on a surface 304, as shown. The protrusions 302 extend from the surface 304 in a direction away from the die 200. The protrusions 302 have the same physical and spatial features as the protrusions 204 described above (e.g., size, shape, pitch, orientation, density, etc.) and thus these features are not described again here. The mold compound 214 covers the various structures of the package 104 and contacts the surface 304 and the protrusions 302. FIG. 3B is a top-down view of the package 104 of FIG. 3A having passivation and polyimide layer protrusions, in accordance with various examples. FIG. 3C is a perspective view of the package 104 of FIG. 3A having passivation and polyimide layer protrusions, in accordance with various examples.

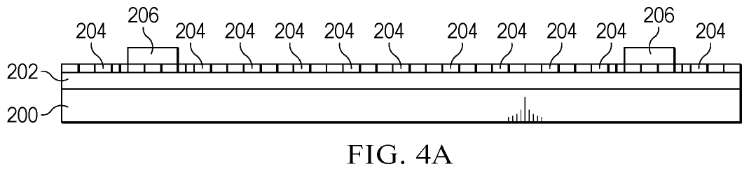

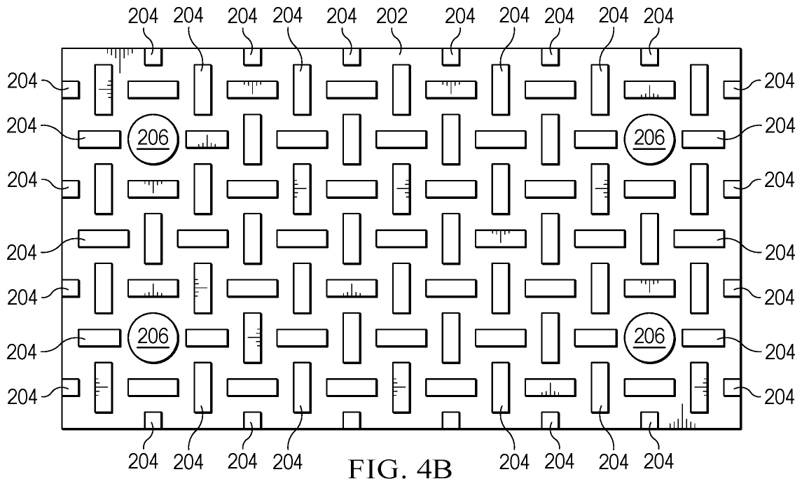

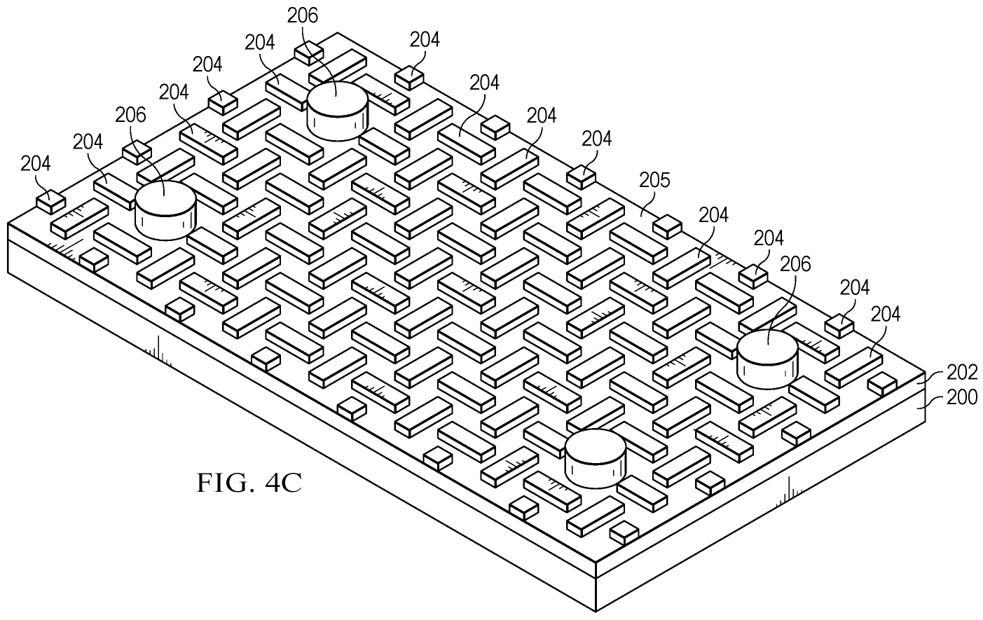

FIG. 4A is a profile view of rectangular passivation layer protrusions 204, in accordance with various examples. FIG. 4B is a top-down view of rectangular passivation layer protrusions 204, in accordance with various examples. FIG. 4C is a perspective view of rectangular passivation layer protrusions 204, in accordance with various examples. Although FIGS. 4A-4C label the protrusions as being passivation layer protrusions 204, FIGS. 4A-4C also may represent polyimide layer protrusions 302, such as those shown and described with reference to FIGS. 3A-3C.

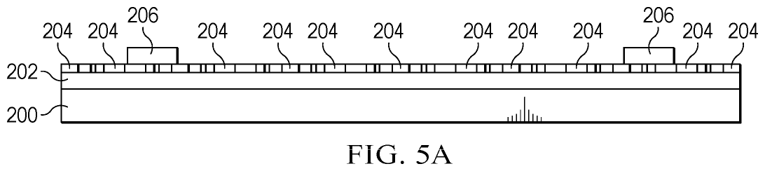

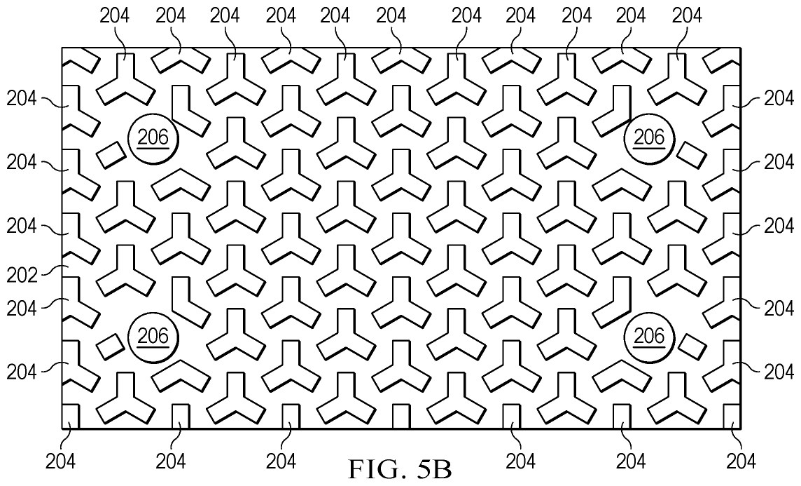

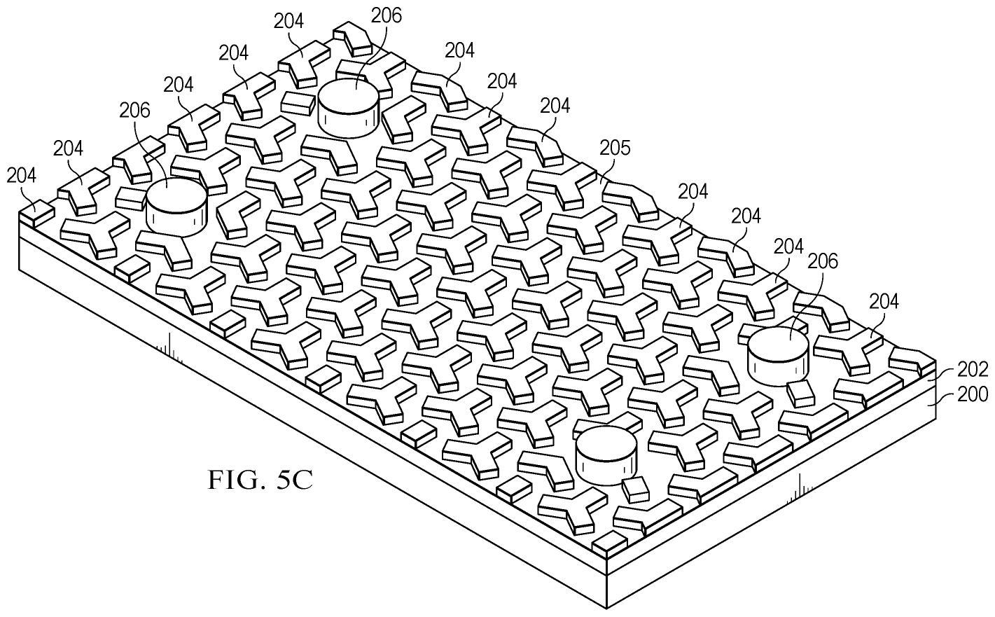

FIG. 5A is a profile view of star-shaped passivation layer protrusions 204, in accordance with various examples. FIG. 5B is a top-down view of star-shaped passivation layer protrusions 204, in accordance with various examples. FIG. 5C is a perspective view of star-shaped passivation layer protrusions 204, in accordance with various examples. Although FIGS. 5A-5C label the protrusions as being passivation layer protrusions 204, FIGS. 5A-5C also may represent polyimide layer protrusions 302, such as those shown and described with reference to FIGS. 3A-3C.

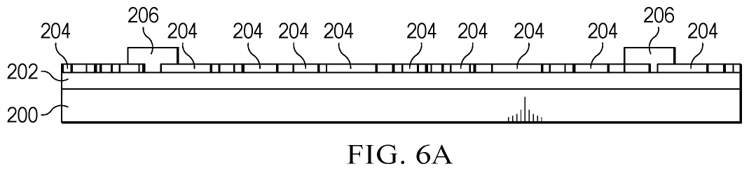

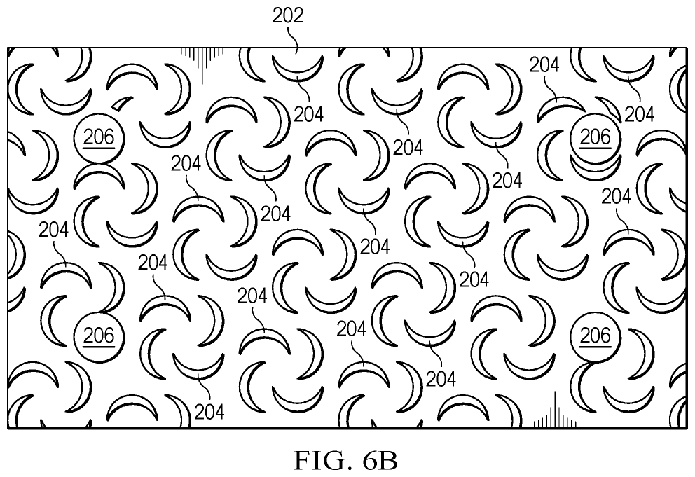

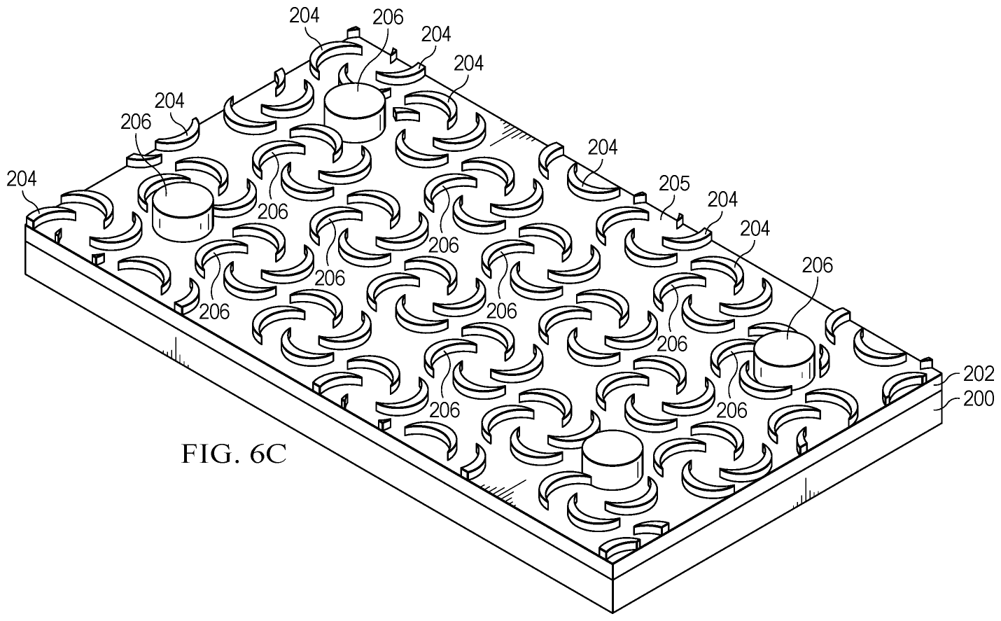

FIG. 6A is a profile view of arc-shaped passivation layer protrusions 204, in accordance with various examples. FIG. 6B is a top-down view of arc-shaped passivation layer protrusions 204, in accordance with various examples. FIG. 6C is a perspective view of arc-shaped passivation layer protrusions 204, in accordance with various examples. Although FIGS. 6A-6C label the protrusions as being passivation layer protrusions 204, FIGS. 6A-6C also may represent polyimide layer protrusions 302, such as those shown and described with reference to FIGS. 3A-3C.

Referring collectively to FIGS. 2A-6C, in operation, charge may creep between metal components of the package 104, such as between metal members 206. The charge may creep along a dielectric interface, such as along the surface 205 between the dielectric layer 202 and the mold compound 214 (FIG. 2A), or such as along the surface 205 between the dielectric layers 202, 300 (FIG. 3A), or such as along the surface 304 between the dielectric layer 300 and the mold compound 214 (FIG. 3A). These creeping charges may have deleterious effects, such as those described above. However, the presence of the protrusions (e.g., protrusions 204, 302) mitigates the creeping of charge along these dielectric interfaces. For example, referring to FIG. 2A, the protrusions 204 mitigate charge creep along the surface 205, between the dielectric layer 202 and the mold compound 214. Charge creep must overcome the physical barriers presented by the protrusions 204, and protrusions 204 that have the specific, critical physical features described herein (i.e., specific length, width, and thickness ranges) are difficult for the charge creep to physically surmount. When charge fails to surmount a protrusion 204, that protrusion 204 is said to have trapped or contained the charge. Protrusions 204 that have physical features within the ranges described herein but that are spaced far apart may provide a clear path for the charge to creep, as may protrusions 204 that provide a clear line-of-sight between metal members (e.g., metal members 206) along which the charge can creep. Thus, protrusions 204 that fall within the specific, critical pitch and density ranges described herein are difficult for the charge creep to physically surmount. In this way, the protrusions 204 are to be regarded as physical obstacles for the charge creep to overcome as the charge attempts to creep between metal members of the package 104. Protrusions 302 operate in the same way as described for the protrusions 204, and thus this operation is not described again here.

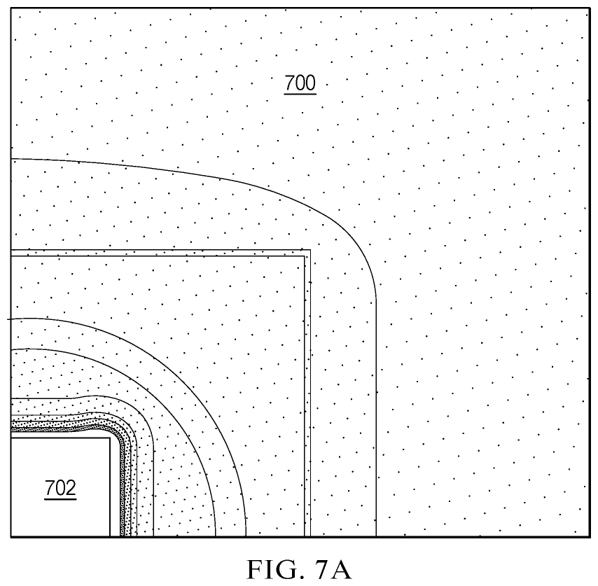

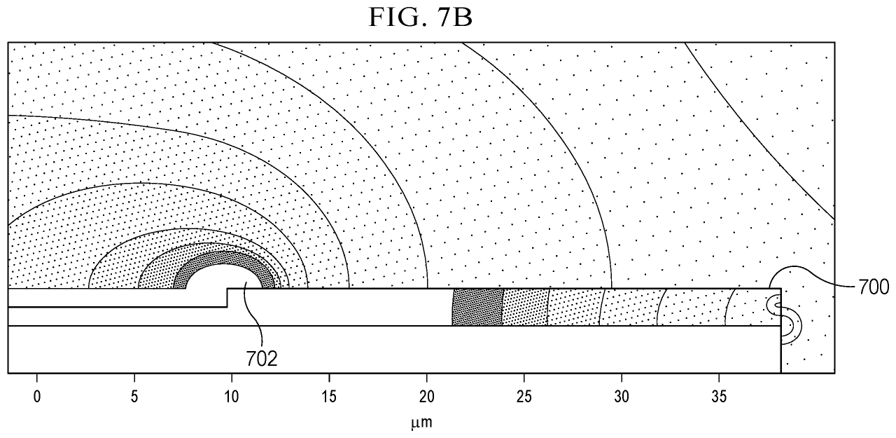

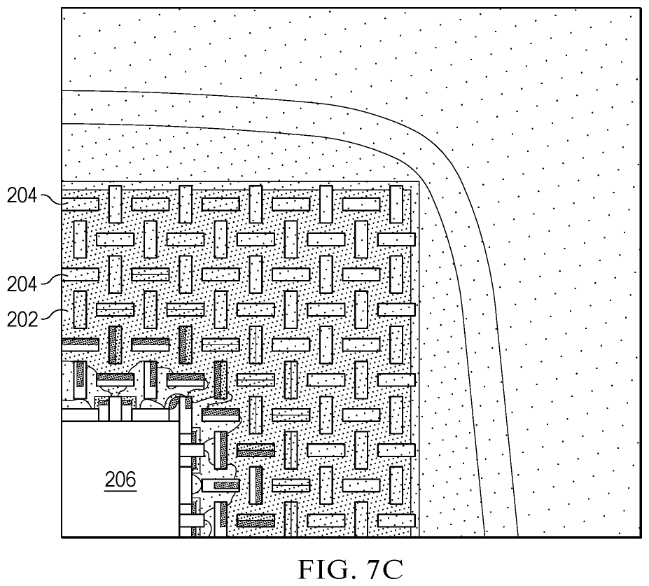

FIGS. 7A-7D are electric field distributions achieved in baseline packages and packages 104 including passivation and/or polyimide layer protrusions, in accordance with various examples. FIG. 7A provides a top-down view of the electric field distribution in a package lacking the protrusions described herein, and FIG. 7B provides a profile, cross-sectional view of the electric field distribution in a package lacking the protrusions described herein. As shown in FIGS. 7A and 7B, the absence of protrusions on surface 700 facilitates charge creep from a metal member 702 along the surface 700. FIG. 7C provides a top-down view of the electric field distribution in a package 104 including protrusions 204 as described herein, and FIG. 7D provides a profile, cross-sectional view of the electric field distribution in a package 104 including protrusions 204 as described herein. As shown, the presence of the protrusions 204 mitigates charge creep from the metal member 206 along the surface 205. In particular, the protrusions 204 trap charge, as shown. The protrusions 302 operate in a similar manner as the protrusions 204, and thus the operation of the protrusions 302 is not repeated herein.

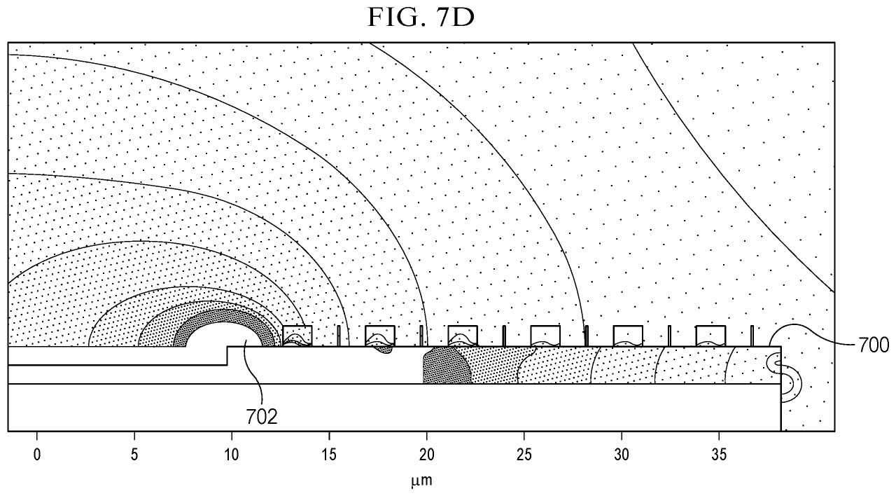

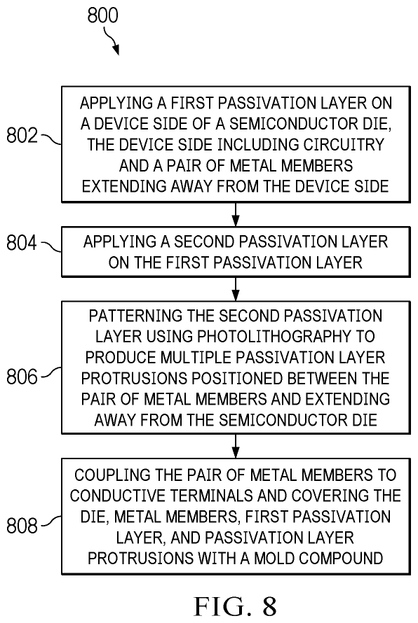

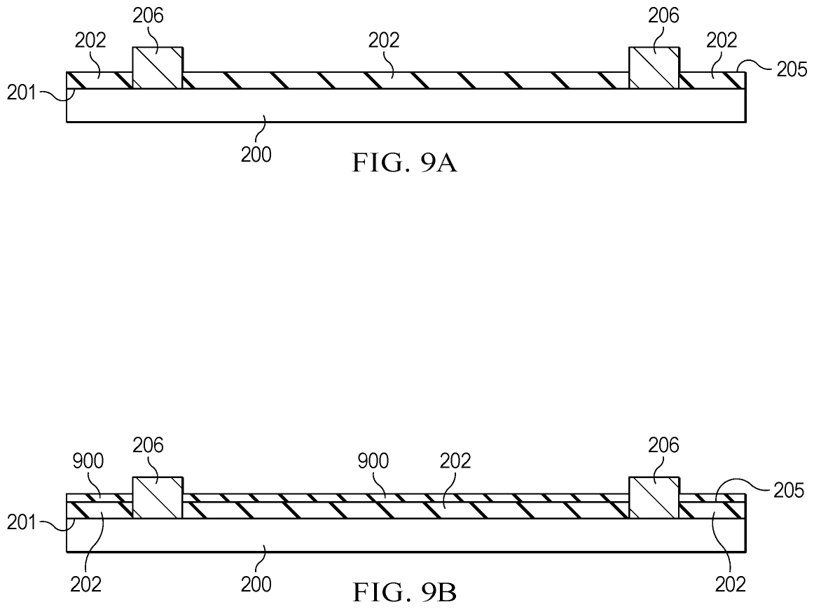

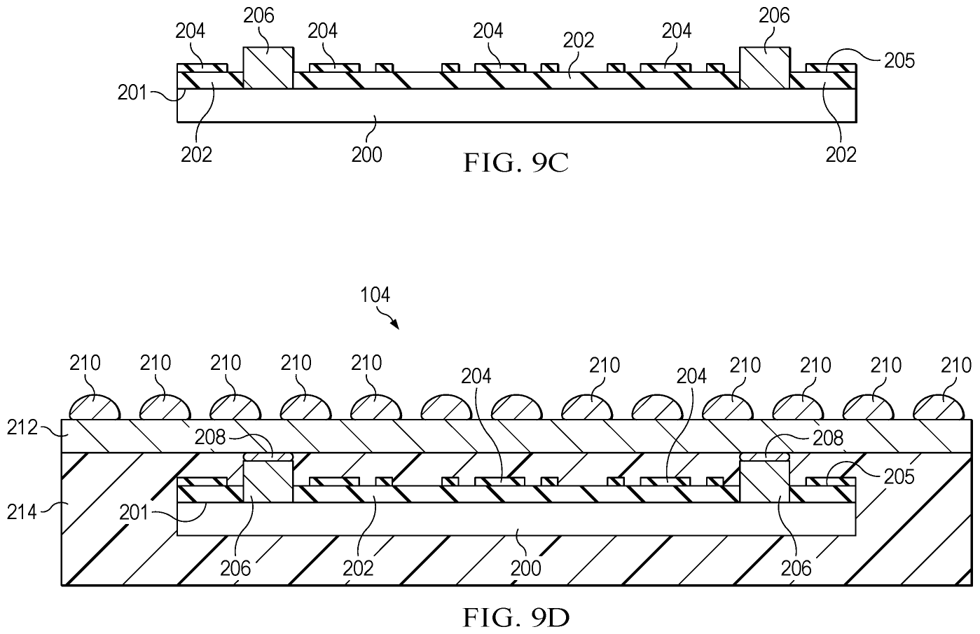

FIG. 8 is a flow diagram of a method 800 for manufacturing a package 104 including passivation layer protrusions, in accordance with various examples. FIGS. 9A-9D is a process flow for manufacturing a package 104 including passivation layer protrusions, in accordance with various examples. Thus, FIGS. 8 and 9A-9D are now described in parallel.

The method 800 includes applying a first passivation layer on a device side of a semiconductor die, with the device side including circuitry and a pair of metal members extending away from the device side (802). FIG. 9A shows metal members 206 formed on a device side 201 of the die 200 and extending away from the device side 201. In addition, the dielectric layer 202 (which may be referred to herein as a passivation layer 202) is on the device side 201.

The method 800 includes applying a second passivation layer on the first passivation layer (804). FIG. 9B shows the structure of FIG. 9A, except that a second passivation layer 900 is applied to the first passivation layer 202. The second passivation layer 900 has a thickness that is the same as that of the protrusions 204 described herein.

The method 800 includes patterning the second passivation layer using photolithographic techniques to produce multiple passivation layer protrusions positioned between the pair of metal members and extending away from the semiconductor die, with the multiple passivation layer protrusions having heights as described herein (806). FIG. 9C shows the structure of FIG. 9B, except that the second passivation layer 900 has been subjected to photolithography (e.g., appropriate positioning of a mask or reticle, light exposure, and development) to form the protrusions 204 described herein.

The method 800 includes coupling the pair of metal members to conductive terminals and covering the die, metal members, and first and second passivation layer protrusions with a mold compound (808). FIG. 9D shows the structure of FIG. 9C, except with the addition of solder members 208, metal bumps 210, RDL 212, and mold compound 214.

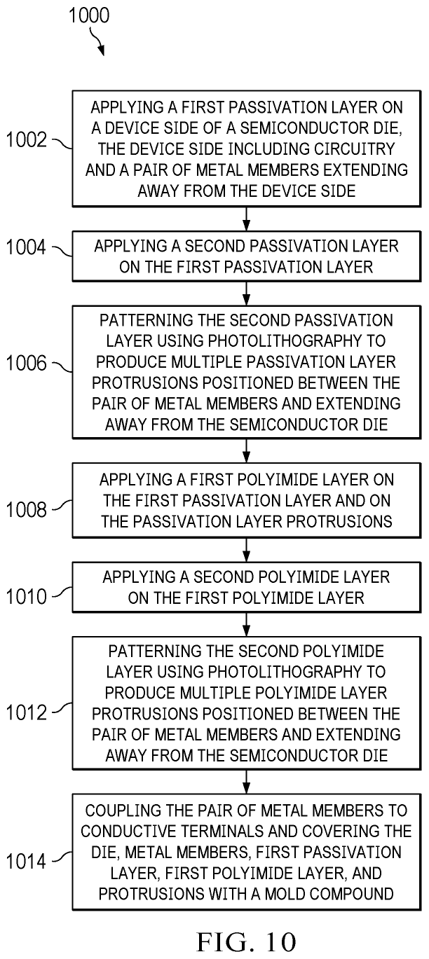

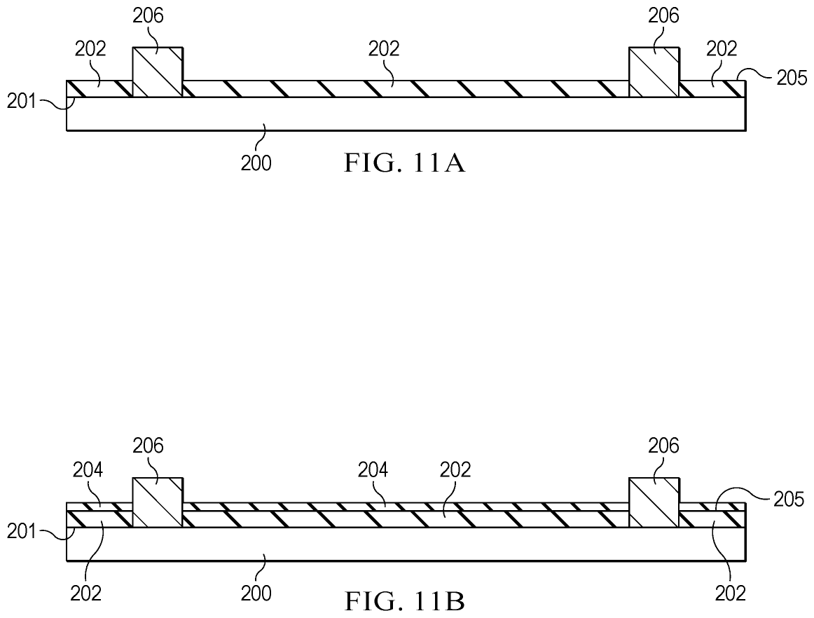

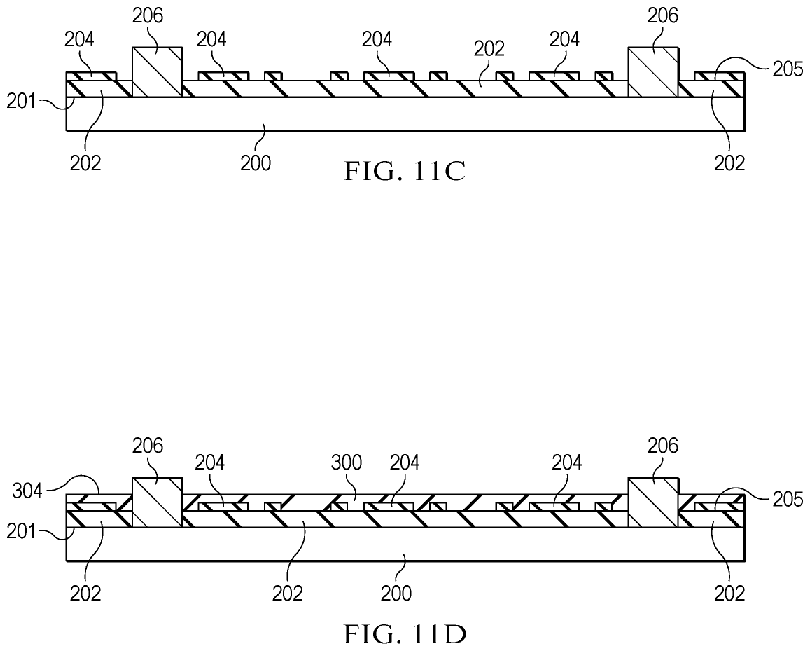

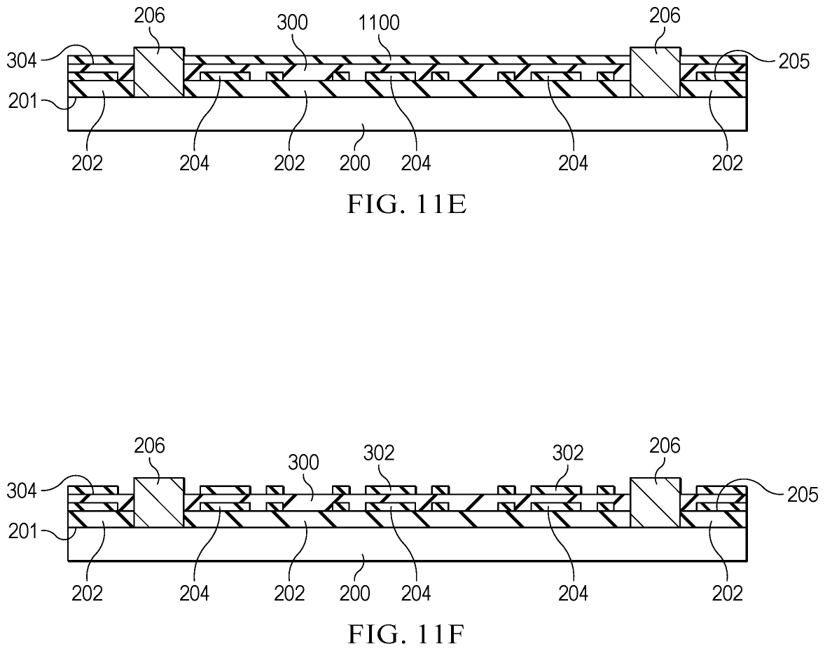

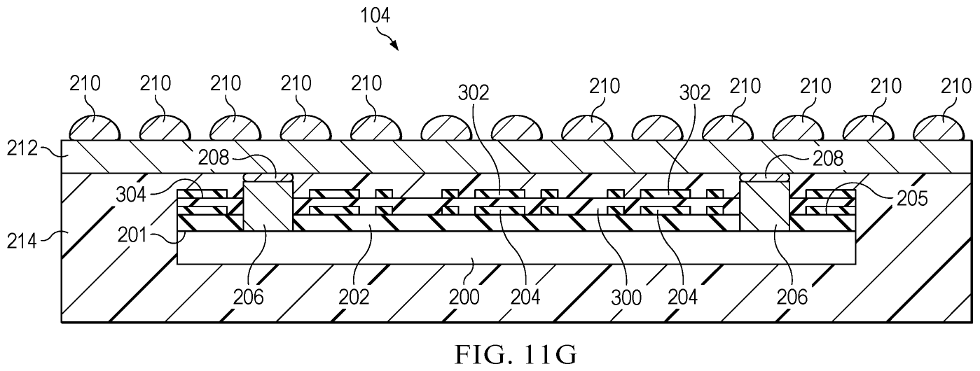

FIG. 10 is a flow diagram of a method 1000 for manufacturing a package 104 including passivation and polyimide layer protrusions, in accordance with various examples. FIGS. 11A-11G is a process flow for manufacturing a package 104 including passivation and polyimide layer protrusions, in accordance with various examples. Accordingly, FIGS. 10 and 11A-11G are now described in parallel.

The method 1000 includes applying a first passivation layer on a device side of a semiconductor die, with the device side including circuitry and a pair of metal members extending away from the device side (1002). FIG. 11A shows metal members 206 formed on a device side 201 of the die 200 and extending away from the device side 201. In addition, the passivation layer 202 is on the device side 201.

The method 1000 includes applying a second passivation layer on the first passivation layer (1004). FIG. 11B shows the structure of FIG. 11A, except that a second passivation layer 900 is applied to the first passivation layer 202. The second passivation layer 900 has a thickness that is the same as that of the protrusions 204, as described herein.

The method 1000 includes patterning the second passivation layer using photolithography to produce multiple passivation layer protrusions positioned between the pair of metal members and extending away from the semiconductor die, with the multiple passivation layer protrusions having heights as described herein (1006). FIG. 11C shows the structure of FIG. 11B, except that the second passivation layer 900 has been subjected to photolithography (e.g., appropriate positioning of a mask or reticle, light exposure, and development) to form the protrusions 204 described herein.

The method 1000 includes applying a first polyimide layer on the first passivation layer and on the passivation layer protrusions (1008). FIG. 11D shows the structure of FIG. 11C, except that the first dielectric layer 300 (which may be referred to herein as the first polyimide layer 300) is applied on the first passivation layer 202 and on the passivation layer protrusions 204.

The method 1000 includes applying a second polyimide layer on the first polyimide layer (1010). FIG. 11E shows the structure of FIG. 11D, except that a second polyimide layer 1100 is applied on the first polyimide layer 300. The second polyimide layer 1100 has a thickness identical to that of the protrusions 302, as described herein.

The method 1000 includes patterning the second polyimide layer using photolithography to produce multiple polyimide layer protrusions positioned between the pair of metal members and extending away from the semiconductor die (1012). FIG. 11F shows the structure of FIG. 11E, except that the second polyimide layer 1100 has been patterned using photolithography into the multiple polyimide layer protrusions 302 described herein.

The method 1000 includes coupling the pair of metal members to conductive terminals and covering the die, metal members, first passivation layer, first polyimide layer, and protrusions with a mold compound (1014). FIG. 11G shows the structure of FIG. 11F, except with the addition of solder members 208, metal bumps 210, RDL 212, and mold compound 214.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A package, comprising:
a semiconductor die having a device side in which circuitry is formed;
first and second metal members coupled to and extending away from the device side;
a passivation layer contacting the device side, at least a portion of the passivation layer positioned between the first and second metal members, the passivation layer including a top surface facing away from the semiconductor die; and
multiple passivation layer protrusions (PLPs) coupled to and extending away from the top surface, the multiple PLPs having heights ranging from 0.5 microns to 50 microns.

2. The package of claim 1, wherein the multiple PLPs form a lattice pattern on the top surface.

3. The package of claim 1, wherein the multiple PLPs have widths ranging from 0.5 microns to 50 microns.

4. The package of claim 1, wherein the multiple PLPs have lengths ranging from 0.5 microns to 50 microns.

5. The package of claim 1, wherein the multiple PLPs form a barrier to a direct line of sight between the first and second metal members.

6. The package of claim 1, wherein a pitch between the multiple PLPs ranges from 0.5 microns to 10 microns.

7. The package of claim 1, wherein the multiple PLPs have cross-sections that are shaped as stars, rectangles, or arcs.

8. The package of claim 1, wherein the multiple PLPs are oriented differently in space.

9. The package of claim 1, further comprising a polyimide layer contacting the top surface of the passivation layer, the polyimide layer having a top polyimide surface facing away from the semiconductor die, the top polyimide surface having multiple additional PLPs extending away from the top polyimide surface.

10. The package of claim 9, wherein the multiple additional PLPs have heights ranging from 0.5 microns to 50 microns, widths ranging from 0.5 microns to 50 microns, and lengths ranging from 0.5 microns to 50 microns.

11. The package of claim 1, wherein top surfaces of the first and second metal members are not covered by the passivation layer.

12. The package of claim 1, wherein the passivation layer is composed of a first material, and the multiple PLPs are composed of a second material that is different from the first material.

13. The package of claim 1, wherein the package is a wafer chip scale package.

14. A package, comprising:
a semiconductor die having a device side in which circuitry is formed;
first and second metal members coupled to the device side;
a passivation layer contacting the device side, at least a portion of the passivation layer positioned between the first and second metal members, the passivation layer including a first top surface facing away from the semiconductor die, the first and second metal members extending away from the device side and past the first top surface;
multiple passivation layer protrusions arranged in a lattice pattern on the first top surface and extending away from the first top surface, the multiple passivation layer protrusions having heights ranging from 0.5 microns to 50 microns, widths ranging from 0.5 microns to 50 microns, lengths ranging from 0.5 microns to 50 microns, and a pitch ranging from 0.5 microns to 10 microns;
a polyimide layer contacting the first top surface, at least a portion of the polyimide layer positioned between the first and second metal members, the polyimide layer including a second top surface facing away from the semiconductor die; and
multiple polyimide layer protrusions arranged in a lattice pattern on the second top surface and extending away from the second top surface, the multiple polyimide layer protrusions having heights ranging from 0.5 microns to 50 microns, widths ranging from 0.5 microns to 50 microns, lengths ranging from 0.5 microns to 50 microns, and a pitch ranging from 0.5 microns to 10 microns.

15. The package of claim 14, wherein the multiple passivation layer protrusions have a density ranging from 1 unit per square micron to 100 units per square micron, and the multiple polyimide layer protrusions have a density ranging from 1 unit per square micron to 100 units per square micron.

16. The package of claim 14, wherein the multiple passivation layer protrusions are formed from a different material than the passivation layer.

17. The package of claim 14, wherein the multiple polyimide layer protrusions are formed from a different material than the polyimide layer.

18. The package of claim 14, wherein the multiple passivation layer protrusions are oriented differently in space, and wherein the multiple polyimide layer protrusions are oriented differently in space.

19. A method for manufacturing a package, comprising:
applying a first passivation layer on a device side of a semiconductor die, the device side including circuitry and a pair of metal members extending away from the device side;
applying a second passivation layer on the first passivation layer; and
patterning the second passivation layer using photolithography to produce multiple passivation layer protrusions positioned between the pair of metal members and extending away from the semiconductor die, the multiple passivation layer protrusions having heights ranging from 0.5 microns to 50 microns and a density ranging from 1 unit per square micron to 100 units per square micron.

20. The method of claim 19, further comprising:
applying a first polyimide layer on the second passivation layer;
applying a second polyimide layer on the first polyimide layer; and
patterning the second polyimide layer using photolithography to produce multiple polyimide layer protrusions positioned between the pair of metal members and extending away from the semiconductor die.

21. The method of claim 19, wherein the multiple passivation layer protrusions have a pitch ranging from 0.5 microns to 10 microns.

22. The method of claim 19, wherein the multiple passivation layer protrusions have lengths ranging from 0.5 microns to 50 microns and widths ranging from 0.5 microns to 50 microns.
